(19) United States
(12) Patent Application Publication
(10) Pub. No.: US 2016/0181500 A1
(43) Pub. Date: Jun. 23, 2016

(54) THERMOELECTRIC CONVERSION DEVICE AND APPLICATION SYSTEM THEREOF

(71) Applicant: INDUSTRIAL TECHNOLOGY RESEARCH INSTITUTE, Chutung (TW)

(72) Inventors: Yu-Li LIN, Chiayi City (TW); Chun-Kai LIN, Toucheng Township (TW); Chien-Hsuan YEH, Zhunan Township (TW)

(21) Appl. No.: 14/738,181

(22) Filed: Jun. 12, 2015

(30) Foreign Application Priority Data
Dec. 23, 2014 (TW) 103144989

(51) Int. Cl. H01L 35/32; H01L 35/30

(52) U.S. Cl. CPC H01L 35/32; H01L 35/30

(57) ABSTRACT

A thermoelectric conversion device and an application system thereof are disclosed. The thermoelectric conversion device includes a first heat exchange element and a thermoelectric conversion element. The first heat exchange element includes a first heat contact portion and a first connection portion. The first heat contact portion is configured to contact with a heat/cold source. The first connection portion has a first insulation surface. The thermoelectric conversion element includes a first electrode layer, a first thermoelectric material and a second thermoelectric material. The first electrode layer is engaged with the first insulation surface. The first thermoelectric material has a first electric property; the second thermoelectric material has a second electric property. The first thermoelectric material and the second thermoelectric material are electrically connected via the first electrode layer.

This application claims the benefit of Taiwan application Serial No. 103144989, filed Dec. 23, 2014, the disclosure of which is incorporated by reference herein in its entirety.

### TECHNICAL FIELD

The disclosure relates in general to a thermoelectric conversion device and an application system thereof, and more particularly to a solid-state thermoelectric conversion device and an application system thereof.

### BACKGROUND

Solid-state thermoelectric conversion technology, which converts thermal energy into electricity or generates heat pump effect when receiving electricity, has been widely used in waste heat recovery for industries or transport vehicles and gradually applied to other fields such as 3C, mobile generator and so on.

The formation of a typical thermoelectric conversion device is as follows. A thermoelectric material (normally, the P-type semiconductor material and the N-type semiconductor material are used at the same time) sliced into a plurality of small pieces are serially connected and bonded onto two insulating substrates, such as two ceramic substrates on two opposite sides. Then, the ceramic substrate disposed on one side is connected to a heat exchanger, such as heat dissipating/conducting fins, by a heat conducting medium to absorb the heat, and the other ceramic substrate disposed on the other side is connected to another heat exchanger by a heat conducting medium to dissipate the heat. When temperature difference is generated between two ends of the thermoelectric material, the electrons inside the thermoelectric material will be driven by the heat to generate power or heat pump effect when connected to an external circuit.

However, the heat conducting medium currently available in the market has a low thermal conductivity, and the interfaces existing between the thermoelectric material and the ceramic substrate and between the ceramic substrate and the heat exchanger will create a certain level of heat resistance. In addition, if there are gaps created between the interfaces due to improper coverage of thermal grease or poor evenness on the bonding surface of the heat exchanger, thermal conduction will be impeded and thermoelectric conversion efficiency will deteriorate. Besides, the heat exchanger normally incurs high cost, particularly when the heat source is in poor condition but a satisfactory effect is desired. Therefore, it has become an imminent task for the thermoelectric conversion industry to provide a thermoelectric conversion device having high thermal conductivity and lower uncertainty risk of system integration to increase the performance/cost ratio of the thermoelectric conversion technology.

Therefore, there is a need to provide an advanced thermoelectric conversion device, an application system thereof and a method for manufacturing the same to resolve the problems encountered in the generally known technology.

### SUMMARY

According to one embodiment, a thermoelectric conversion device is disclosed. The thermoelectric conversion device comprises a first heat exchange element and a thermoelectric conversion unit. The first heat exchange element comprises a first heat contact portion and a first connection portion. The first heat contact portion is configured to contact with a heat/cold source. The first connection portion has a first insulation surface. The thermoelectric conversion element comprises a first electrode layer, a first thermoelectric material and a second thermoelectric material. The first electrode layer is engaged to and in conformal contact with the first insulation surface. The first thermoelectric material has a first electric property. The second thermoelectric material has a second electric property. The first thermoelectric material and the second thermoelectric material are electrically connected via the first electrode layer.

According to another embodiment, a thermoelectric conversion system is disclosed. The thermoelectric conversion system comprises a first heat exchange element, a thermoelectric conversion unit and a first flow channel structure. The first heat exchange element comprises a first heat contact portion and a first connection portion having a first insulation surface. The thermoelectric conversion element comprises a first electrode layer, a first thermoelectric material and a second thermoelectric material. The first electrode layer is engaged to and in conformal contact with the first insulation surface. The first thermoelectric material has a first electric property. The second thermoelectric material has a second electric property. The first thermoelectric material and the second thermoelectric material are electrically connected via the first electrode layer. The first flow channel structure has at least one faying surface enabling the first heat contact portion in contact with a fluid via a faying surface.

The above and other aspects of the disclosure will become better understood with regard to the following detailed description of the preferred but non-limiting embodiment(s). The following description is made with reference to the accompanying drawings.

### BRIEF DESCRIPTION OF THE DRAWINGS

FIG. 1 is flowchart illustrating a method for manufacturing a thermoelectric conversion device according to one embodiment of the disclosure.

FIGS. 1A˜1E are cross-sectional views illustrating the processing structures for manufacturing the thermoelectric conversion device of FIG. 1.

FIG. 2 is a structural cross-sectional view illustrating a thermoelectric conversion device according to another embodiment of the disclosure.

FIG. 3 is a structural cross-sectional view illustrating a thermoelectric conversion device according to an alternative embodiment of the disclosure.

FIG. 4 is a structural cross-sectional view illustrating a thermoelectric conversion device according to yet another embodiment of the disclosure.

FIG. 5 is a structural cross-sectional view illustrating a thermoelectric conversion system according to yet another embodiment of the disclosure.

FIGS. 6A˜6E are structural top views illustrating variations of a flow channel structure according to some other embodiments of the disclosure.

FIG. 7 is a structural cross-sectional view illustrating a thermoelectric conversion system according to another embodiment of the disclosure.

FIGS. 8A and 8B are perspective views respectively illustrating an exploded structure and an assembly structure of a thermoelectric conversion system according to one embodiment of the disclosure.

FIG. 9 is a structural cross-sectional view of a thermoelectric conversion system according to an alternative embodiment of the disclosure.

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

### DETAILED DESCRIPTION

The present specification discloses a number of embodiments related to a thermoelectric conversion device, an application system thereof and a method for manufacturing the same for resolving the problems encountered in generally known technology such as poor thermal conduction efficiency, high structure cost and the control of the quality of system assembly. To make the above purposes, features and advantages of the disclosure easy to understand, a number of exemplary embodiments with accompanying drawings are disclosed below with detailed descriptions.

It should be noted that these embodiments and methods are not for limiting the disclosure. The disclosure can also be implemented by using other technical features, elements, methods and parameters. A number of exemplary embodiments are disclosed for illustrating technical features of the disclosure, not for limiting the claims of the disclosure. Anyone who is skilled in the technology field of the disclosure can make necessary modifications or variations to the structures according to the needs in actual implementations. In different drawings and embodiments, the same elements are represented by the same designations.

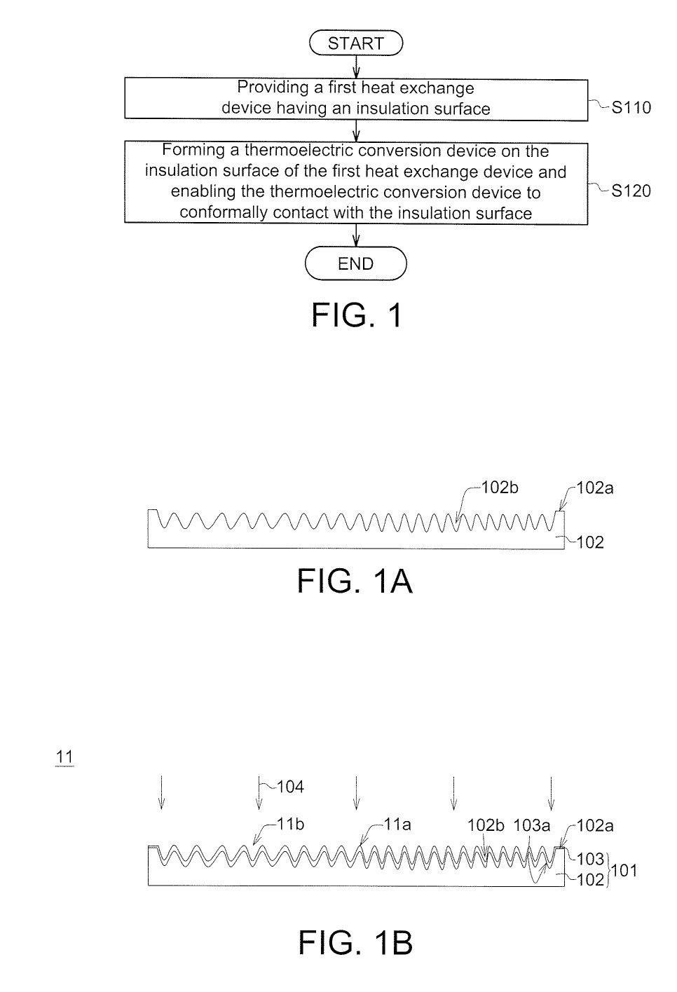

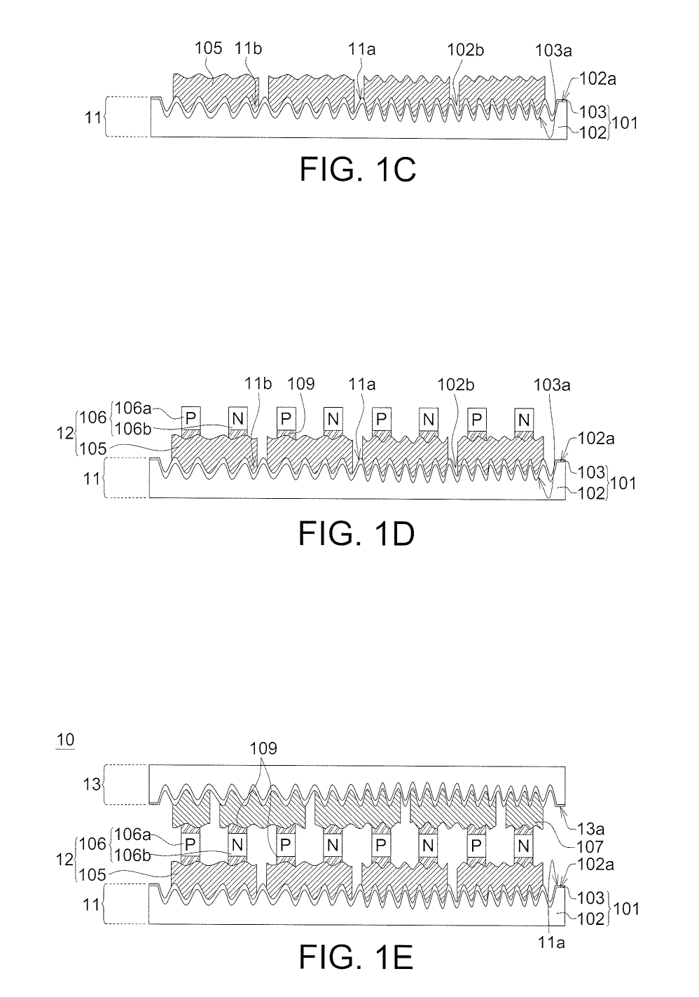

FIG. 1 is a flowchart illustrating a method for manufacturing a thermoelectric conversion device 10 according to one embodiment of the disclosure. FIGS. 1A˜1E are cross-sectional views illustrating the processing structures for manufacturing the thermoelectric conversion device 10 of FIG. 1.

The method for manufacturing the thermoelectric conversion device 10 comprises following steps: Firstly, the method begins at step S110, a first heat exchange element 11 having an insulation surface 11a is provided. The first heat exchange element 11 comprises a substrate 101 having excellent thermal conduction effect. The substrate 101 comprises a heat contact portion configured to contact with a heat/cold source, and a connection portion having an insulation surface. In one embodiment of the disclosure, the substrate 101 can be realized by a single-layered structure formed of an insulating material or a multi-layered structure formed of an insulating material and/or other different materials. For example, the substrate 101 can be realized by a composite substrate composed of dielectric material, metal semiconductor or a combination thereof.

In the present embodiment, the substrate 101 can be realized by a metal substrate 102 comprising a dielectric layer 103. The dielectric layer 103 covers on a surface 102a of the metal substrate 102. The portion of the metal substrate 102 covered by the dielectric layer 103 can serve as a connection portion of the substrate 101. The opposite side of the metal substrate 102 corresponding to the connection portion can serve as a heat contact portion of the substrate 101. The metal substrate 102 can be formed of gold (Au), silver (Ag), copper (Cu), iron (Fe), stainless steel, aluminum (Al), tungsten (W) or other metal or a combination thereof. Preferably, the metal substrate 102 can be an aluminum substrate. The thickness of the aluminum substrate substantially ranges between 1 mm˜5 mm, and preferably is equal to 2 mm.

The process for providing the first heat exchange element 11 comprises steps as follows: A roughening treatment 104, such as sandblasting treatment, is performed on the surface 102a of the metal substrate 102 to form a plurality of recesses 102b on the surface 102a of the metal substrate 102 and make the roughness of the surface 102a of the metal substrate 102 substantially between 10 μm˜100 μm (as illustrated in FIG. 1A). Then, a dielectric layer 103 is formed on the surface 102a of the metal substrate 102 in a manner of making a surface 103a of the dielectric layer 103 (referred as contact surface 103a hereinafter) further being engaged to and in conformal contact with the surface 102a of the metal substrate 102. In other words, the dielectric layer 103 not only horizontally (superficially) covers the surface 102a of the metal substrate 102 but also vertically extends into the recesses 102b formed on the metal substrate 10 for covering the sidewalls and bottoms thereof 2, whereby the surface of the dielectric layer 103 opposite to the contact surface 103a serves as an insulation surface 11a (as illustrated in FIG. 1B).

In some embodiments of the disclosure, the dielectric layer 103 can be formed on the surface 102a of the metal substrate 102 by using deposition process. The dielectric layer 103 can be formed of silicon nitride, silicon oxide, silicon carbide, nitrogen silicon oxide, aluminum nitride, alumina or a combination thereof. In some other embodiments of the disclosure, the dielectric layer 103 can be realized by a metal nitride layer or a metal oxide layer formed on the rough surface 102a of the metal substrate 102 by using metal nitration process or metal oxidation process. The thickness of the dielectric layer 103 substantially ranges between 0.01 mm˜0.1 mm and preferably is equal to 0.03 mm.

In the present embodiment, the dielectric layer 103 is an aluminum nitride layer or an alumina layer formed on the rough surface 102a of the metal substrate 102 by using metal nitration process or metal oxidation process. It should be noted that the formation of the dielectric layer 103 is not limited to the above exemplifications, and any methods suitable for forming a dielectric layer in conformal contact with the metal substrate 102 can be used to forming the dielectric layer 103.

Next, the method proceeds to step S120, a thermoelectric conversion element 12 is formed on and in conformal contact with the insulation surface 11a of the first heat exchange element 11. In some embodiments of the disclosure, the formation of the thermoelectric conversion element 12 comprises following steps: Firstly, a patterned electrode layer 105 is formed on and in conformal contact with the insulation surface 11a. In some embodiments of the disclosure, the patterned electrode layer 105 can be realized by a patterned metal layer formed on the insulation surface 11a by using deposition process and etching process. In some other embodiments of the disclosure, the formation of the patterned electrode layer 105 is not limited to the above exemplification. The patterned electrode layer 105 can also be formed on the insulation surface 11a by using stamping process, electroplating process or any other suitable methods.

In the present embodiment, since the dielectric layer 103 does not completely fulfill the recess 102b, thus there are still a plurality of recesses 11b formed on the insulation surface 11a in a manner of substantially overlapping the recess 102b of the metal substrate 102. Therefore, the patterned electrode layer 105 can be subsequently grown on the insulation surface 11 a according to the surface topography of the insulation surface 11a. In other words, the patterned electrode layer 105 can not only horizontally (superficially) cover the insulation surface 11a but also vertically extend into the recesses 11b for covering the sidewalls and bottoms thereof (as illustrated in FIG. 1C). As a result the thermoelectric conversion element 12 can be more firmly engaged with the first heat exchange element 11.

Then, a plurality of the thermoelectric conversion units 106 are formed on the patterned electrode layer 105. Each thermoelectric conversion unit 106 at least comprises a thermoelectric material 106a having first electrical property and a thermoelectric material 106b having second electrical property electrically contacting with the patterned electrode layer 105 respectively. The thermoelectric conversion units 106 are mutually conducted via the patterned electrode layer 105. It should be noted that two thermoelectric materials having the same electric property are mutually insulated.

In some embodiments of the disclosure, the first thermoelectric material 106a and the second thermoelectric material 106b are respectively formed of a semiconductor material having P-type electric property and a semiconductor material having N-type electric property, wherein these two types of semiconductor materials are divided into small blocks. In the present embodiment, the first thermoelectric material 106a and the second thermoelectric material 106b are connected to the patterned electrode layer 105 by soldering. Since the solder 109 connecting the patterned electrode layer 105 to the first thermoelectric material 106a and the second thermoelectric material 106b also can be coated on the electrode layer 105 according to the surface topography of the patterned electrode layer 105, thus the bonding strength formed between the patterned electrode layer 105 and the first thermoelectric material 106a and the second thermoelectric material 106b can be enhanced (as illustrated in FIG. 1D).

Then, the first thermoelectric material 106a and the second thermoelectric material 106b of a plurality of the thermoelectric conversion units 106 are serially connected by wires (not illustrated) to form the thermoelectric conversion elements 12 composed by a plurality of P-type semiconductor blocks and N-type semiconductor blocks. Temperature difference existing between two ends of each semiconductor block of the thermoelectric conversion element 12 may drive heat flowing from the high temperature side to the low temperature side. Meanwhile, the electron carriers of the N-type semiconductor blocks and the hole carriers of the P-type semiconductor blocks are driven by the heat flow, so as to generate direct current, when the thermoelectric conversion element is connected to an external wire.

In some embodiments of the disclosure, the thermoelectric conversion device 10 further comprises a second heat exchange element 13. The structure of the second heat exchange element 13 is substantially identical to that of the first heat exchange element 11. The second heat exchange element 13 also has an insulation surface 13a in conformal contact with the thermoelectric conversion element 12. In the present embodiment, the wires serially connecting the first thermoelectric material 106a and the second thermoelectric material 106b of a plurality of the thermoelectric conversion units 106 can be analogously replaced by the patterned conductive layer 107 on the insulation surface 13a of the second heat exchange element 13 to form a thermoelectric conversion device 10 as illustrated in FIG. 1E.

Since the thermoelectric conversion element 12 can be conformally formed on the rough insulation surfaces 11a and 13a of the first heat exchange element 11 and the second heat exchange element 13, the thermal conductivity interface between the first heat exchange element 11 and the thermoelectric conversion element 12 as well as the thermal conductivity interface between the thermoelectric conversion element 12 and the second heat exchange element 13 can be more tightly engaged. The heat flux between the first heat exchange element 11 and the thermoelectric conversion element 12 as well as the heat flux between the thermoelectric conversion element 12 and the second heat exchange element 13 can be effectively increased, and better resistance to stress can be generated therebetween.

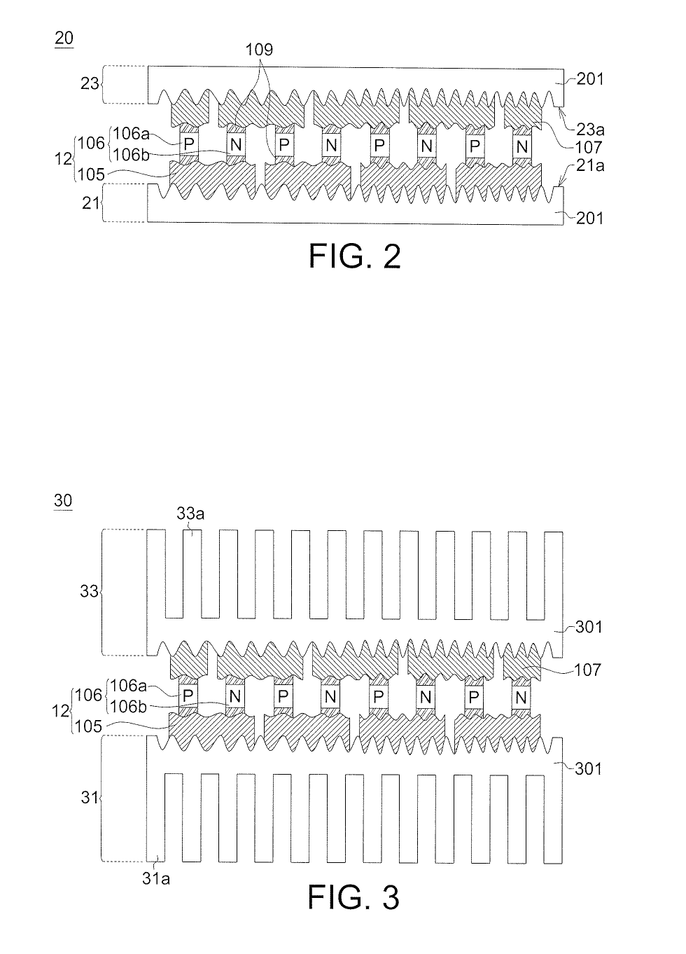

Referring to FIG. 2, FIG. 2 is a structural cross-sectional view illustrating a thermoelectric conversion device 20 according to another embodiment of the disclosure. The structure of the thermoelectric conversion device 20 is substantially identical to that of the thermoelectric conversion device 10 depicted in FIG. 1E except that the first heat exchange element 21 and the second heat exchange element 23 of the thermoelectric conversion device 20 are formed of the ceramic substrate 201, and the dielectric layer of the connection portion is omitted. In the present embodiment, after the roughening treatment (such as sandblasting treatment) is performed on the ceramic substrates 201 of the first heat exchange element 21 and the second heat exchange element 23, the roughened surfaces of the ceramic substrate 201 of the first heat exchange element 21 and the second heat exchange element 23 can serve as the insulation surfaces 21a and 23a of the connection portions of the first heat exchange element 21 and the second heat exchange element 23, such that the ceramic substrates 201 of the first heat exchange element 21 and the second heat exchange element 23 can be directly engaged to and in conformal contact with the thermoelectric conversion element 12. The thickness of the ceramic substrates 201 substantially ranges between 0.1 mm˜2 mm and preferably is equal to 0.5 mm. The opposite side of the ceramic substrates 201 of the first heat exchange element 21 and the second heat exchange element 23 corresponding to the connection portions of the first heat exchange element 21 and the second heat exchange element 23 are the heat contact portions of the first heat exchange element 21 and the second heat exchange element 23 respectively.

In some embodiments of the disclosure, preferably the first heat exchange element 31 and the second heat exchange element 33 have at least one protrusion portions 31a and 33a respectively used as a heat exchange structure at the hot end for receiving a heat source and a heat exchange structure at the cold end for receiving a cold source. Referring to FIG. 3, FIG. 3 is a structural cross-sectional view illustrating a thermoelectric conversion device 30 according to an alternative embodiment of the disclosure. The structure of the thermoelectric conversion device 30 is substantially identical to that of the thermoelectric conversion device 20 depicted in FIG. 2 except that both the first heat exchange element 31 and the second heat exchange element 33 of the thermoelectric conversion device 30 have fins, finger-like projections, or blocks with porous surface area (protrusion portions 31a and 33a) projected on the heat contact portions of the ceramic substrates 301 to increase the heat dissipating/absorbing surface areas of the first heat exchange element 31 and the second heat exchange element 33.

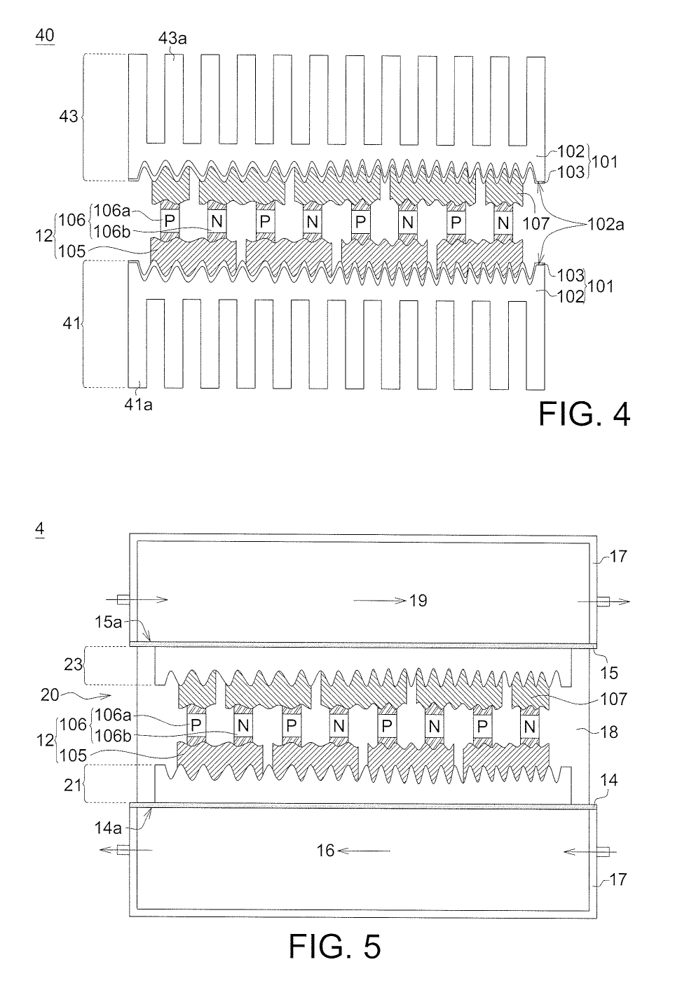

Referring to FIG. 4, FIG. 4 is a structural cross-sectional view illustrating a thermoelectric conversion device 40 according to another alternate embodiment of the disclosure. The structure of the thermoelectric conversion device 40 is substantially identical to that of the thermoelectric conversion device 10 depicted in FIG. 1E except that both the first heat exchange element 41 and the second heat exchange element 43 of the thermoelectric conversion device 40 have fins, finger-like projections, or blocks with porous surface area (protrusion portions 41a and 43a) projected on the heat contact portions of the substrate 101 depicted in FIG. 1E to increase the heat dissipating/absorbing surface areas of the first heat exchange element 41 and the second heat exchange element 43. The fins, finger-like projections, or blocks with porous surface area are projected on the opposite side of the rough surfaces 102a of the metal substrates 102 depicted in FIG. 1E. The surfaces of these fins, finger-like projections, or blocks with porous surface area can be a smooth surface (i.e. on which there is any dielectric layers 103 formed) or an anti-erosion layer comprising silicon nitride, silicon oxide, silicon carbide, nitrogen silicon oxide, titanium nitride, chromium nitride, aluminum nitride, alumina or a combination thereof can be formed by deposition, oxidation or nitration process and available for resisting an environment containing metal corrosive substances.

The thermoelectric conversion device can be integrated with flow channel structures, such as flow-channel connecting plates 14 and 15, to form a thermoelectric conversion system, wherein the flow channel structures provide a space for a heat supplying fluid (hot fluid) and a heat dissipating fluid (cold fluid) to flow through. Referring to FIG. 5, FIG. 5 is a structural cross-sectional view illustrating a thermoelectric conversion system 4 according to one embodiment of the disclosure. In the present embodiment, the thermoelectric conversion device 20 can be integrated with two flow-channel connecting plates 14 and 15 to form a thermoelectric conversion system 4. The flow-channel connecting plates 14 and 15 can be realized by two divider structures having faying surfaces 14a and 15a respectively. Given that the requirements of tightness and pressure resistance are satisfied, the flow-channel connecting plates 14 and 15 can be disposed in the sidewalls of the container or pipe 17 of the heat dissipating fluid 19 or the heat supplying fluid 16 by way of soldering or other methods to separate the thermoelectric conversion device 20 from the heat dissipating fluid 19 and the heat supplying fluid 16. One end of the flow-channel connecting plate 14 contacts with the first heat exchange element 21 of the thermoelectric conversion device 20; the other end of the flow-channel connecting plate 14 contacts with the heat supplying fluid 16. One end of the flow-channel connecting plate 15 contacts with the second heat exchange element 23 of the thermoelectric conversion device 20; the other end of the flow-channel connecting plate 15 directly contacts with the heat dissipating fluid 19.

In some embodiments of the disclosure, the peripheral area of the contact interface between the flow-channel connecting plate 14 and the first heat exchange element 21 of the thermoelectric conversion device 20 as well as the interface between the flow-channel connecting plate 15 and the second heat exchange element 23 of the thermoelectric conversion device 20 are normally coated with a layer of heat-resistant sealant 18 to prevent the cold fluid and the hot fluid leaked from the peripheral area of the contact interfaces, so as to infiltrate the first thermoelectric material 106a and the second thermoelectric material 106b of the thermoelectric conversion unit 106. In some embodiments of the disclosure, the heat-resistant sealant 18 can completely wrap up each thermoelectric conversion unit 106 of the thermoelectric conversion device 10. The thickness of the heat-resistant sealant 18 substantially ranges between 1 mm˜5 mm and preferably is equal to 2 mm.

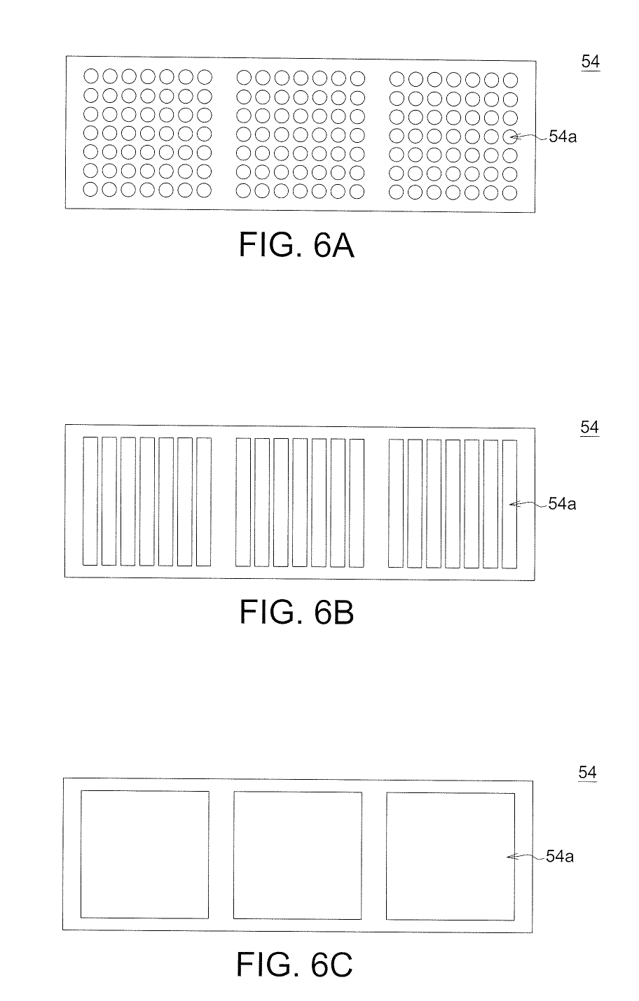

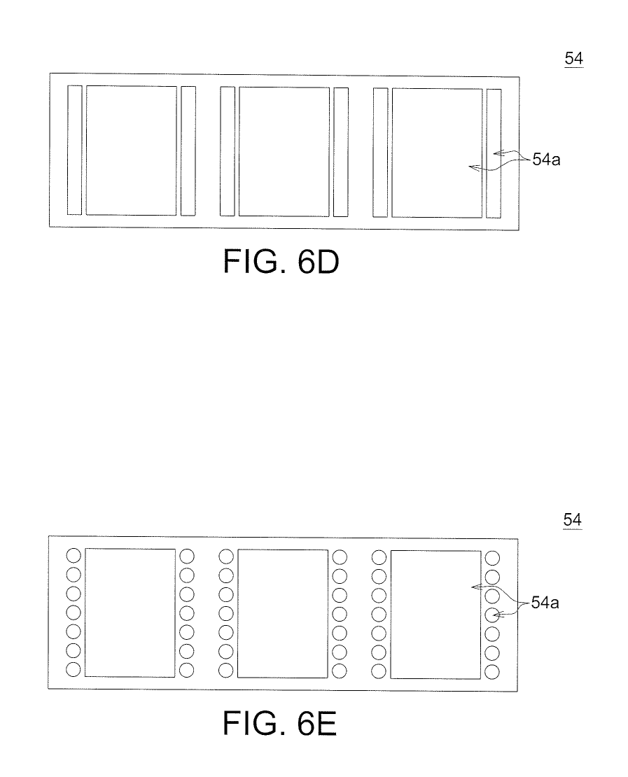

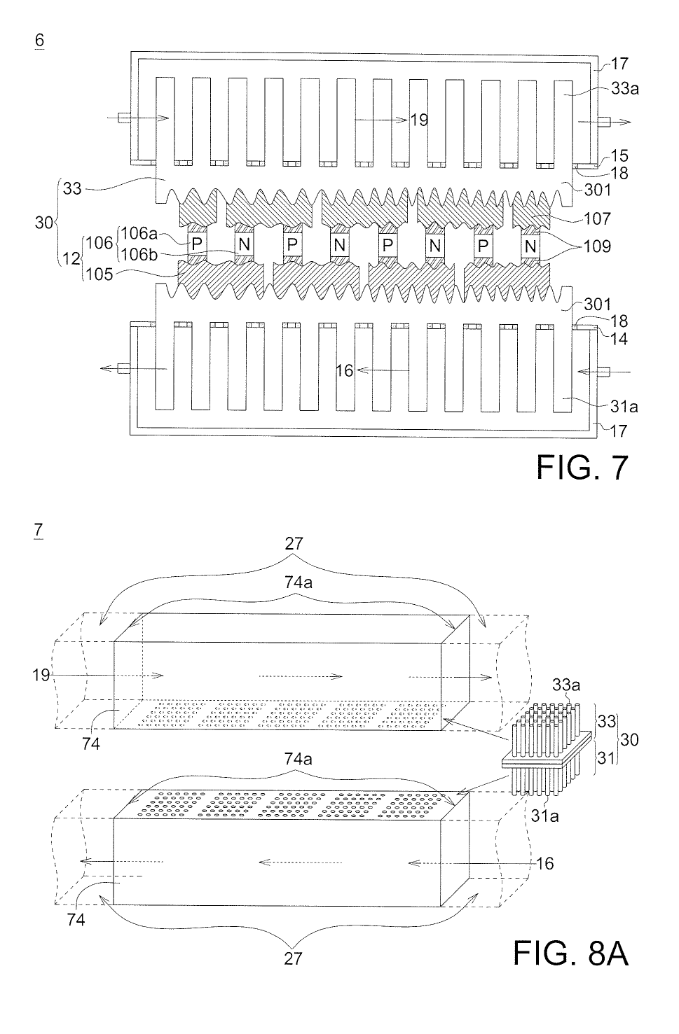

Referring to FIGS. 6A˜6E, FIGS. 6A˜6E are structural top views illustrating variations of a flow channel structure according to some other embodiments of the disclosure. Both the flow channel structure 54 illustrated in FIGS. 6A˜6E and the flow-channel connecting plates 14 or 15 illustrated in FIG. 5 are a divider structure. The difference between the two types of divider structures lies in that each flow channel structure 54 has a plurality of openings 54a allowing the protrusion portions 31a and 33a or 41a and 43a of the thermoelectric conversion device 30 or 40 illustrated in FIG. 3 or FIG. 4 to pass through, such that the protrusion portions 31a and 33a or 41a and 43a of the thermoelectric conversion device 30 or 40 can be directly embedded into the container or pipe 17 carrying the heat dissipating fluid 19 or the heat supplying fluid 16 to form the thermoelectric conversion system 6 as illustrated in FIG. 7, whereby the protrusion portions 31a and 33a or 41a and 43a of the thermoelectric conversion device 30 or 40 can respectively be contact with the heat dissipating fluid 19 and the heat supplying fluid 16 directly.

The opening 54a of the flow channel structure 54 can have several variations based on the shape and size of the protrusion portions 31a and 33a (or 41a and 43a) of the thermoelectric conversion device 30 (or 40). In some embodiments of the disclosure, to prevent the heat dissipating fluid 19 and the heat supplying fluid 16 leaking form the interfaces between the opening 54a of the flow channel structure 54 and the protrusion portions 31a and 33a of the thermoelectric conversion device 30, normally a layer of heat-resistant sealant 18 (as illustrated in FIG. 7) is interposed between the sidewalls of the opening 54a of the flow channel structure 54 and the protrusion portions 31a and 33a of the thermoelectric conversion device 30.

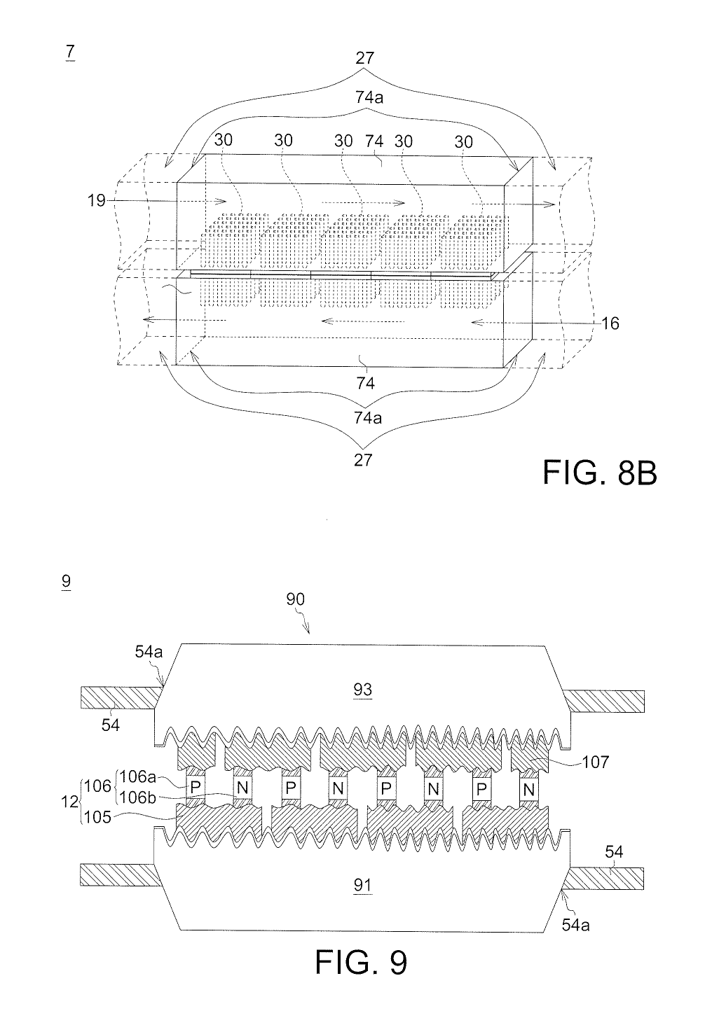

Referring to FIG. 8A and FIG. 8B, FIG. 8A and FIG. 8B are perspective views respectively illustrating an exploded structure and an assembly structure of a thermoelectric conversion system 7 according to yet another embodiment of the disclosure. The structure of the thermoelectric conversion system 7 is substantially identical to that of the thermoelectric conversion system 6 except that the flow channel structure 74 of the thermoelectric conversion system 7 is interconnected with the pipe 27 carrying the heat dissipating fluid 19 or the heat supplying fluid 16, and two sides of the flow channel structure 74 respectively have a faying surface 74a interconnected with the pipe 27 and allowing the heat dissipating fluid 19 or the heat supplying fluid 16 to pass there through. Moreover, one flow channel structure 74 can collocate with a plurality of thermoelectric conversion devices 30. Because each thermoelectric conversion device 30 is independently and tightly engaged with the flow channel structure 74, thus if one of the thermoelectric conversion device 30 is not tightly engaged with the flow channel structure 74, it will not affect the engagement between other thermoelectric conversion device 30 and the flow channel structure 74.

After the thermoelectric conversion device 30 are embedded, the thermoelectric conversion device 30 can be enveloped in the space between two channels 74 by soldering, interposing cotton insulation to or coating sealant (not illustrated), whereby the peripheral and the exposed portions of the thermoelectric conversion device 30 can be isolate to avoid the thermoelectric conversion device 30 from being oxidized by the external air or being infiltrated by condensing water droplets.

Furthermore, the thermoelectric conversion device and the channels can be integrated through a configuration design of faying surface without having to seal the holes with sealant. Referring to FIG. 9, FIG. 9 is a structural cross-sectional view illustrating a thermoelectric conversion system 9 according to an alternate embodiment of the disclosure. In the present embodiment, the first heat exchange element 91 and the second heat exchange element 93 of the thermoelectric conversion device 90 can directly be embedded into the opening 54a of the flow channel structure 54 as illustrated in FIG. 6C, in a manner of sealing the opening 54a by applying a pressure thereon and omitting the step of sealing the opening 54a with sealant.

In the present embodiment, the structure of the thermoelectric conversion device 90 is substantially identical to that of the thermoelectric conversion device 10 as illustrated in FIG. 1E except that the first heat exchange element 91 and the second heat exchange element 93 of the thermoelectric conversion device 90 is shaped as a conic cone gradually narrower towards the anterior end. It should be noted that the opening 54a of the flow channel structure 54 also has a shape, in collaboration with the shape of the first heat exchange element 91 and the second heat exchange element 93, gradually flared from one entrance towards the other. The dimension of the first heat exchange element 91 and the second heat exchange element 93 is slightly larger than that of the opening 54a. When the first heat exchange element 91 and the second heat exchange element 93 are tightly pressed to be engaged with the opening 54a, the first heat exchange element 91 and the second heat exchange element 93 can be tightly integrated with the flow channel structure 54. Particularly, when the first heat exchange element 91 and the second heat exchange element 93 are formed of a material softer than that of the flow channel structure 54, the first heat exchange element 91 and the second heat exchange element 93 can be integrated more tightly with the flow channel structure 54. For example, the first heat exchange element 91 and the second heat exchange element 93 are formed of aluminum and the flow channel structure 54 is formed of stainless steel.

Based on the above disclosure, the embodiments of the disclosure disclose a thermoelectric conversion device and an application system thereof and a method for manufacturing the same. By enabling the thermoelectric material of the thermoelectric conversion unit to conformally contact the insulation surface of the dissipation fins of the heat exchange element, the thermoelectric conversion unit and the heat exchange element are directly integrated into one piece, and the thermal conductivity interface between the thermoelectric conversion unit and the heat exchange element can thus be reduced. Therefore, the heat resistance is largely reduced, and the thermoelectric conversion efficiency is increased.

The thermoelectric conversion unit and the heat exchange element can further incorporate a flow channel structure to form a thermoelectric conversion system, in which the heat exchange element can be tightly engaged with the flow channel structure and passes through the flow channel structure to directly contact with the cold fluid or the hot fluid to achieve a better thermal conduction effect and further simplify the structure of the thermoelectric conversion system and reduce the configuration cost. Meanwhile, individual thermoelectric conversion device is independently engaged with the flow channel structure and will not affect the engagement between other thermoelectric conversion device and the flow channel structure as long as individual thermoelectric conversion device is tightly engaged with the flow channel structure and the cold fluid and the hot fluid do not leak through. Thus, the evenness requirement of the faying surface between the heat exchanger and a plurality of thermoelectric modules of a conventional thermoelectric conversion system can be satisfied.

In one embodiment, there is a sealant interposed between the thermoelectric conversion device and the flow channel structure. Before the sealant is cured, the sealant is a soft material, and can fully interpose and seal the pores between the thermoelectric conversion device and the flow channel structure regardless whether the faying surface between the flow channel structure and thermoelectric conversion device is even or not. In comparison to the generally known thermoelectric conversion system, the thermoelectric conversion device and system of the disclosure have the technical advantage of simply structure and easy assembly. Meanwhile, the thermoelectric conversion device and system of the disclosure is capable of reducing heat resistance, decreasing configuration cost and avoiding the unevenness between the heat exchanger and the thermoelectric modules affecting the efficiency during the assembly of the thermoelectric conversion system. Therefore, the performance/cost ratio of the thermoelectric conversion technology is largely increased.

It will be apparent to those skilled in the art that various modifications and variations can be made to the disclosed embodiments. It is intended that the specification and examples be considered as exemplary only, with a true scope of the disclosure being indicated by the following claims and their equivalents.

1. A thermoelectric conversion device, comprising:
a first heat exchange element having a plurality of recesses, comprising:
a first heat contact portion, configured to contact with one of a heat source and a cold source; and
a first connection portion where the plurality of recesses are formed, having a first insulation surface; and
a thermoelectric conversion element, comprising:
a first electrode layer, at least partially extending into the recesses and engaged with the first insulation surface;
a first thermoelectric material, having a first electric property; and
a second thermoelectric material, having a second electric property, wherein the first thermoelectric material and the second thermoelectric material are electrically connected via the first electrode layer.

2. The thermoelectric conversion device according to claim 1, wherein the first heat contact portion comprises a first portion of a metal substrate; and the first connection portion comprises:
a second portion of the metal substrate, wherein the second portion has a rough surface having the plurality of recesses; and
a dielectric layer, disposed on the second portion and having the first insulation surface and a contact surface, wherein the contact surface is disposed on an opposite side of the first insulation surface and engaged with the rough surface.

3. The thermoelectric conversion device according to claim 2, wherein the metal substrate comprises aluminum and the dielectric layer comprises alumina or aluminum nitride.

4. The thermoelectric conversion device according to claim 1, wherein the first heat contact portion comprises a first portion of a ceramic substrate; and the first connection portion comprises a second portion of the ceramic substrate, wherein the second portion has a rough surface which has the plurality of recesses and serves as the first insulation surface.

5. The thermoelectric conversion device according to claim 1, further comprising a second heat exchange element, wherein the second heat exchange element comprises:
a second connection portion having a second insulation surface configured to contact with a second electrode layer of the thermoelectric conversion element, wherein the second electrode layer is electrically connected with one of the first thermoelectric material and the second thermoelectric material; and
a second heat contact portion configured to contact with the other one of the heat source and the cold source.

6. The thermoelectric conversion device according to claim 1, wherein the first heat contact portion has a protrusion portion.

7. The thermoelectric conversion device according to claim 6, wherein the protrusion portion comprises a fin, a finger-like projection, or a porous block with high specific surface area.

8. A thermoelectric conversion system, comprising:
at least one thermoelectric conversion device, wherein the thermoelectric conversion device comprises:
a first heat exchange element, comprising:
a first heat contact portion; and
a first connection portion, having a first insulation surface;
a thermoelectric conversion element, comprising:
a first electrode layer, engaged with the first insulation surface;
a first thermoelectric material, having a first electric property; and
a second thermoelectric material, having a second electric property, wherein the first thermoelectric material and the second thermoelectric material are electrically connected via the first electrode layer; and
a first flow channel structure having at least a faying surface which contacts the first heat contact portion and connects the first flow channel structure and the thermoelectric conversion device enabling the first heat contact portion to contact with a fluid via the faying surface.

9. The thermoelectric conversion system according to claim 8, wherein the first heat contact portion comprises a first portion of a metal substrate; and the first connection portion comprises:
a second portion of the metal substrate, wherein the second portion has a rough surface; and
a dielectric layer, disposed on the second portion and having the first insulation surface and a contact surface, wherein the contact surface is disposed on an opposite side of the first insulation surface and engaged with the rough surface.

10. The thermoelectric conversion system according to claim 9, wherein the metal substrate comprises aluminum and the dielectric layer comprises alumina or aluminum nitride.

11. The thermoelectric conversion system according to claim 8, wherein the first heat contact portion comprises a first portion of a ceramic substrate; and the first connection portion comprises a second portion of the ceramic substrate, wherein the second portion has a rough surface serving as the first insulation surface.

12. The thermoelectric conversion system according to claim 8, further comprising a second heat exchange element, wherein the second heat exchange element comprises:
a second connection portion having a second insulation surface configured to contact with a second electrode layer of the thermoelectric conversion element, wherein the second electrode layer is electrically connected with one of the first thermoelectric material and the second thermoelectric material; and
a second heat contact portion configured to contact with the other one of the heat source and the cold source.

13. The thermoelectric conversion system according to claim 8, wherein the first heat contact portion has a protrusion portion.

14. The thermoelectric conversion system according to claim 13, wherein the protrusion portion comprises a fin, a finger-like projection, or a porous block with high specific surface area.

15. The thermoelectric conversion system according to claim 8, further comprising:
a second heat exchange element in contact with the thermoelectric conversion element; and
a second flow channel structure whose one end is adjacent to the second heat exchange element and the other end contacts with another fluid.

16. The thermoelectric conversion system according to claim 8, wherein the faying surface has at least one opening allowing the first heat contact portion passing through the opening and contacting with the fluid.
